(19) United States
(12) Patent Application Publication
(10) Pub. No.: US 2006/0139867 A1
(43) Pub. Date: Jun. 29, 2006

(54) Adjustable base

(76) Inventor: Hsien-Chin Chiang, Sindian City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/316,937

(22) Filed: Dec. 27, 2005

(30) Foreign Application Priority Data
Dec. 29, 2004 (TW) 093141217

(51) Int. Cl. G06F 1/16; H05K 7/04

(52) U.S. Cl. 361/683; 361/807

(57) ABSTRACT

An adjustable base for carrying a device movably comprises a base body having at least two supporting portions which are extending and protruding from the base body oppositely and respectively. Additionally, one supporting portion is exposed greater than the other supporting portion when the device is moved to a position away from the middle of the adjustable base.

### TECHNICAL FIELD

This invention relates generally to a base used for supporting a device, and more particularly to an adjustable base, which shortens the distance between the device thereon and a wall so as to save space greatly.

### BACKGROUND OF THE INVENTION

As shown in FIG. 10, a conventional base 8 is used for supporting a device 7 to be straighten up, wherein the base 8 is assembled to a certain bottom of the device 7 and has two protruding portions which are extending from the base 8 and protruding outward two opposites of the bottom of the device 7 respectively; however, the base 8 is engagable only on the certain bottom of the device 7 so that the two exposed protruding portions of the base 8 must occupy a certain space. Therefore, when the device 7 is placed near against a wall 5, there must be a great wasted space between one side of the device 7 and the wall 5 where the device 7 cannot move closer to the wall in the result of the limit of the protruding portions.

From the foregoing it will be seen that room exists for improvements in the base.

### SUMMARY OF INVENTION

The primary objective of the present invention is to provide an adjustable base which is assembled to a bottom of a device movably to shorten the distance between the device and a wall so as to save space.

More particularly, the base body has two supporting portions extending from the base body and protruding outward the two opposites of the bottom of the device. While the device is adjusted to a position away from the middle of the adjustable base, one of the supporting portions is exposed greater than the other supporting portion. In the meantime, the short other supporting portion is suitably for against the wall to shorten space between the device and the wall.

### BRIEF DESCRIPTION OF DRAWINGS

The features and advantages of an adjustable base according to the present invention will be more clearly understood from the following description taken in conjunction with the accompanying drawings in which:

FIG. 1 is a perspective view of a first embodiment of the present invention, showing a device and an adjustable base;

FIG. 2A is a front view of the first embodiment of the present invention, showing the device assembled onto the adjustable base;

FIG. 2B is a top view of the first embodiment of the present invention, showing the device assembled onto the adjustable base;

FIG. 3A is a front view of the first embodiment of the present invention, showing the device adjusted rightward a position away from the middle of the adjustable base and close to a wall;

FIG. 3B is a top view of the first embodiment of the present invention, showing the device adjusted rightward a position away from the middle of the adjustable base and close to the wall;

FIG. 4A is a front view of the first embodiment of the present invention, showing the device adjusted leftward a position away from the middle of the adjustable base and close to a wall;

FIG. 4B is a top view of the first embodiment of the present invention, showing the device adjusted leftward a position away from the middle of the adjustable base and close to the wall;

FIG. 5 is a partial cross sectional view of the first embodiment of the present invention; showing the device assembled against the adjustable base;

FIG. 6 is a partial cross sectional view of the first embodiment of the present invention; showing the device lifted up from the adjustable base;

FIG. 7 is a partial cross sectional view of a second embodiment of the present invention, showing a device assembled onto an adjustable base;

FIG. 8 is a top view of a third embodiment of the present invention, showing a device assembled onto two base bodies;

FIG. 9 is an exploded perspective view of a fourth embodiment of the present invention, showing a device, an adapter and a base body; and

FIG. 10 shows a conventional base.

### DETAILED DESCRIPTION OF PREFERRED EMBODIMENTS

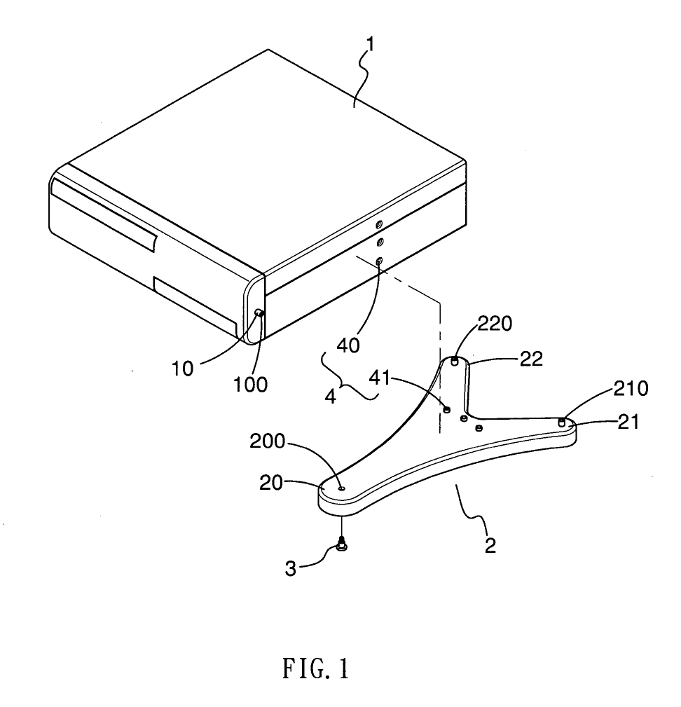

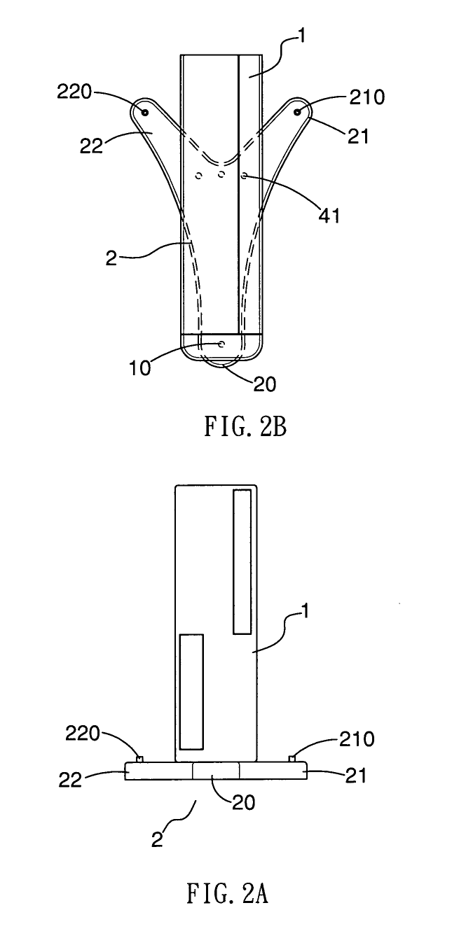

As shown in FIG. 1, an adjustable base according to the first embodiment of the present invention is provided for supporting a device 1 to be straightened up through screwing a base body 2 onto a bottom of the device 1 by at least one screw 3. As shown in FIG. 2A, the device 1 is a computer host or an electric device or goods in need of being straightened up.

Referring again to FIG. 1, on the bottom of the device 1 has a pivot 10 with a hole 100 or a threaded hole therein. The base body 2 has a pivot section 20, two supporting portions 21 (a first supporting portion 21 and a second portions 22), in which the pivot section 20 has a notch 200 thereon for receiving the pivot 10, therefore, the base body 2 can pivot on the pivot 10. Moreover, the screw 3 is cross the notch 200 of the base body 2 and screwed into the hole 100 of the pivot 10.

As illustrated in FIG. 1, there is a positioning structure 4 disposed between the device 1 and the base body 2 to allow the base body 2 engaging with a certain bottom of the device 1. The positioning structure 4 comprises three setting holes 40 arranged in order along a circle arc whose center is the pivot 10 at a suitably distance from the pivot 10 and on the bottom of the device 1, and three setting bolts 41 protruding from a top of the base body 2 for wedging into the setting holes 40.

As for the FIGS. 1, 2A and 2B, there is illustrated the two supporting portions 21,22 extending from the base body 2 and protruding outward the two opposites of the bottom of the device 1 and having a first limiting pillar 210 and a second limiting pillar 220 formed thereon respectively. FIGS. 2A and 2B show the device 1 is disposed in the middle of the base body 2, and the first and second supporting portions 21,22 are exposed equally.

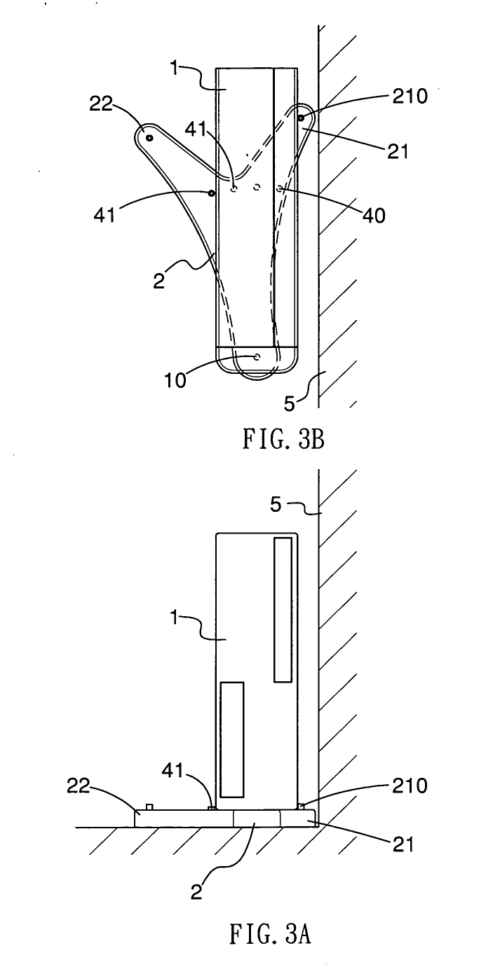

As shown in FIGS. 3A and 3B, the device 1 is adjusted to pivot rightward a certain degree on the pivot 10 such that two right side setting bolts 41 of the base body 2 are wedged into two left side setting holes 40, meanwhile, the exposed first supporting portion 21 is greatly reduced and the first limiting pillar 210 thereon is against the right side of the device 1 so as to stop the device 1 move out. Thus, the space between the right side of the device 1 and a wall 5 is greatly reduced.

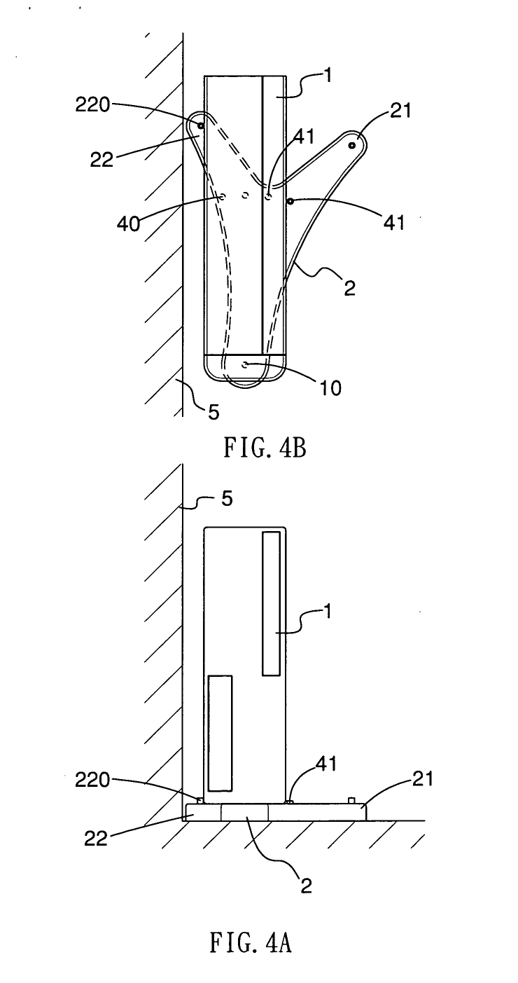

FIGS. 4A and 4B show the device 1 is adjusted to pivot leftward a certain degree on the pivot 10 such that two left side setting bolts 41 of the base body 2 are wedged into two right side setting holes 40, meanwhile, the exposed second supporting portion 22 is greatly reduced and the second limiting pillar 220 thereon is against the left side of the device 1 so as to prevent the device 1 from moving out from the adjustable base. Thus, the space between the left side of the device 1 and the wall 5 is greatly reduced.

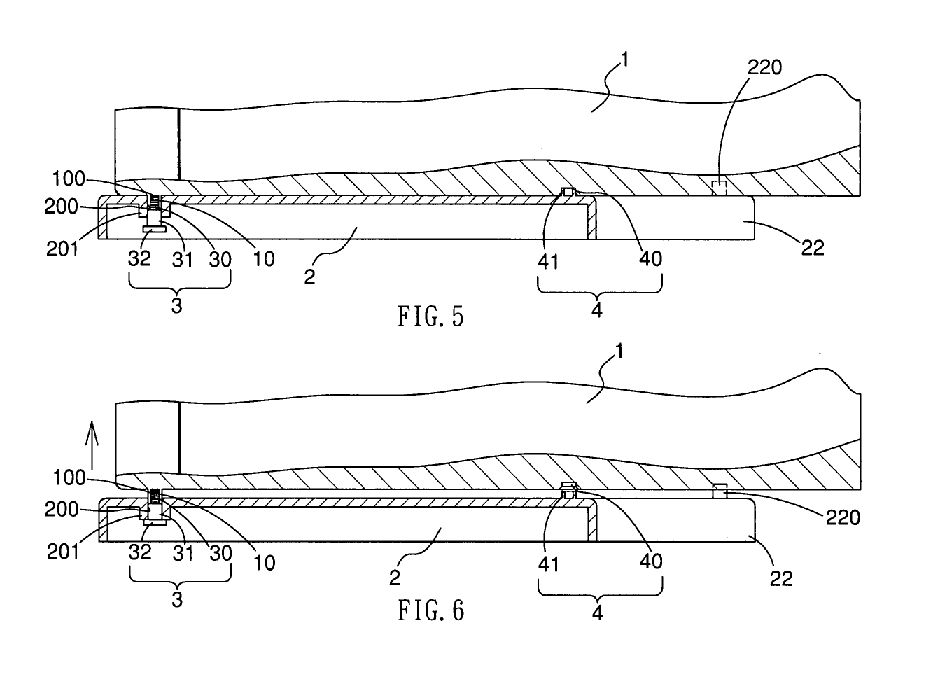

FIG. 5 shows a more detailed illustration of the notch 200 which has a flange 201 extending thereunder and the screw 3 having a thread 30, a body 31, and a head 32, wherein the thread 30 is cross the notch 200 and screwed onto the hole 100 of the pivot 10; the body 31 is provided for rotating and sliding up and down within the notch 200; and the head 32 is able to against an end of the flange 201 so as to limit a sliding range when the device 1 is lifted up.

FIG. 6 shows the device 1 can only be lifted upward to a certain height X that is higher than the height of the setting bolts 41 but lower than the second limiting pillar 220; moreover, the first limiting pillar 210 is as high as the second limiting pillar 220 as shown in FIG. 2. Thus, while being lifted up or pivoted on the pivot 10, the device 1 will not be blocked by the setting bolts 41 but by the first limiting pillar 210 or the second limiting pillar 220. Furthermore, it is clearly understood that the first limiting pillar 210 or the second limiting pillar 220 is regarded as the positioning point while the device 1 is pivoted on the base body 2. According to this, the first limiting pillar 210 or the second limiting pillar 220 is against one side of the device 1 and the setting pillars 41 are properly wedged into the setting holes 40 respectively and correspondingly.

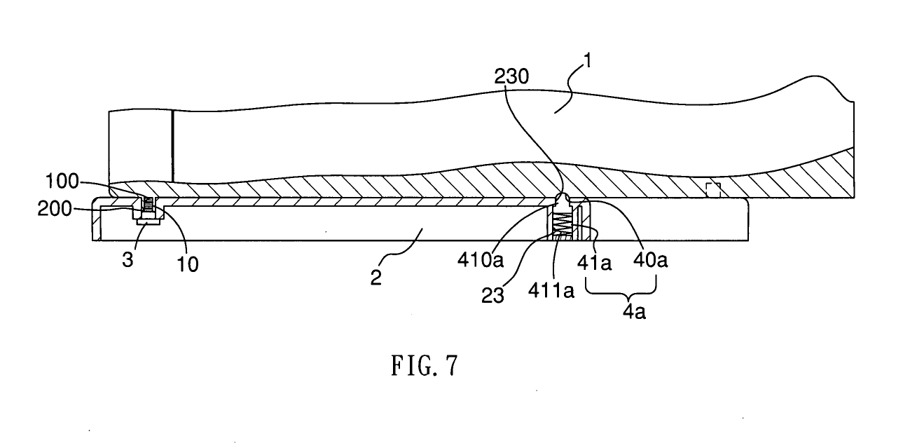

FIG. 7 shows a second embodiment of the present invention. Comparing with the first embodiment, there is no difference between the first and the second embodiments in the present invention but only the positioning structure 4a of the second embodiments of the present invention. The positioning structure 4a comprises a plurality of setting cavities 40a disposed on the bottom of the device 1 at a suitable distance from the pivot 10 and arranged in order along a circle arc whose center is the pivot 10; and an elastic setting part 41a provided for being wedged into the setting holes 40a, which is disposed in a recess 23. The recess 23 is formed on the base body 2 and has a small diameter opening 230 theretop. Furthermore, the elastic setting part 41a comprises a setting bolt 410a being cross the opening 230 and wedged into the setting holes 40a; and a compression spring 411a allowing to push the setting bolt 41a upwardly.

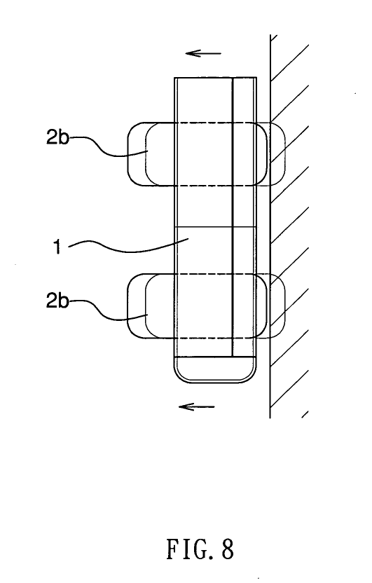

FIG. 8 shows a preferred third embodiment of the present invention. Similar to the first embodiment of the present invention, but the third embodiment of the present invention has two base bodies 2b different from only one base body of the first embodiment of the present invention. Wherein, the two base bodies 2b can be assembled on to the bottom of the device 1 separately and the two base bodies 2b are movable transversely.

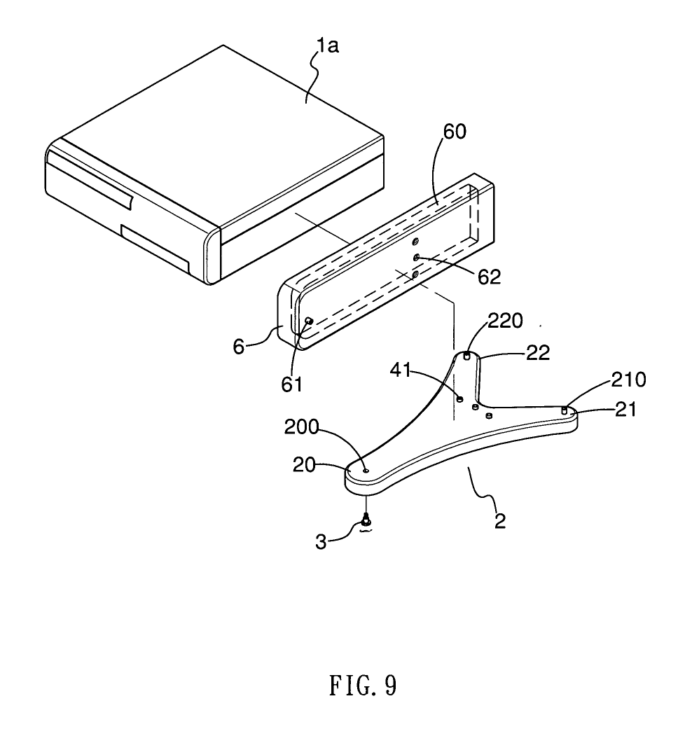

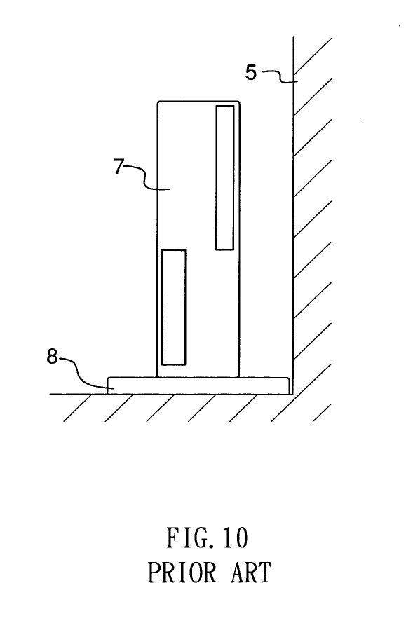

FIG. 9 shows a preferred fourth embodiment of the present invention. Both the first and the fourth embodiment of the present invention are similar but an added adapter 6 is further provided in the fourth embodiment of the present invention to carry the device 1 of the first embodiment of the present invention. In other words, the adjustable base of the fourth embodiment mainly comprises the base body 2 and the adapter 6, which is provided for carrying a device 1a, like a computer host or any other electric device or goods in need of being straightened up, and the adapter 6 has a chamber 60 formed theretop for installing the device 1a. Besides, on the bottom of the adapter 6 has a bolt 61 and holes 62 providing for coupling with the corresponding notch 200 and the corresponding setting bolts 41 of the base body 2 respectively so that the adapter 6 can rotate and be positioned on the base body 2.

Numerous characteristics and advantages of the invention have been set forth in the foregoing description, together with details of the structure and function of the invention, and the novel features thereof are pointed out in appended claims. The disclosure, however, is illustrated only, and changes may be made in detail, especially, in matters of shape, size and arrangement of parts, materials and the combination thereof within the principle of the invention, to the full extent indicated by the broad general meaning of the terms in which the appended claims are expressed.

We claim:

1. An adjustable base for carrying a device movably, comprising a base body having at least two supporting portions which are extending and protruding from the base body oppositely and respectively; wherein, one supporting portion is exposed greater than the other supporting portion when the device is moved to a position away from the middle of the adjustable base.

2. The adjustable base as claimed in claim 1, wherein the base body comprises a positioning structure for setting the device to be disposed on a top of the base body.

3. The adjustable base as claimed in claim 2, wherein the positioning structure of the base body comprises at least one setting bolt standing out from the top of the base body for engaging with the device.

4. The adjustable base as claimed in claim 3, wherein the base body comprises a notch theretop to allow the device pivoting on the base body.

5. The adjustable base as claimed in claim 4, further comprising at lease one screw for securing the base body and the device via the notch of the base body, and wherein the at least one screw has a thread provided for engaging with the device; a body provided for rotating and sliding up and down within the notch; and a head provided for against an end of the notch so as to limit a sliding range of the body so that the device can be lifted up to a limited top-height which is higher than the height of the setting bolt.

6. The adjustable base as claimed in claim 5, wherein each of the at least two supporting portions further comprises a limiting pillar formed thereon, the limiting pillar being higher than the limited top-height of the device.

7. The adjustable base as claimed in claim 2, wherein the positioning structure of the base body comprises an elastic setting part for wedging into the device.

8. The adjustable base as claimed in claim 1, further comprising an adapter movably connected with the base body for receiving the device.

9. The adjustable base as claimed in claim 8, wherein the adapter has a chamber for installing the device.

10. The adjustable base as claimed in claim 9, wherein the adapter further comprises at least one setting hole formed therebottom; and the base body comprises at least one setting bolt standing out from a top of the base body for engaging with the setting hole of the adapter.

11. The adjustable base as claimed in claim 10, wherein the adapter further comprises a pivot thereunder and the base body has a notch theretop for receiving the pivot of the adapter so as to allow the adapter pivoting on the base body.

12. The adjustable base as claimed in claim 11, further comprising at least one screw for securing the base body and the adapter via the notch of the base body, and wherein the at least one screw has a thread provided for engaging with the pivot of the adapter; a body provided for rotating and sliding up and down within the notch of the base body; and a head provided for against an end of the notch of the base body so as to limit a sliding range of the body so that the adapter can be lifted up to a limited top-height which is higher than the height of the setting bolt.

13. The adjustable base as claimed in claim 12, wherein each of the at least two supporting portions further comprises a limiting pillar formed thereon, the limiting pillar being higher than the limited top-height of the adapter.

14. The adjustable base as claimed in claim 9, wherein the base body comprises an elastic setting part theretop for wedging into a bottom of the adapter.
